(19) United States
(12) Patent Application Publication
(10) Pub. No.: US 2008/0170951 A1
(43) Pub. Date: Jul. 17, 2008

(54) PIEZOELECTRIC PUMP

(75) Inventor: Akira SATOH, Niigata-ken (JP)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: Alps Electric Co., Ltd., Ota-ku (JP)

(21) Appl. No.: 12/014,995

(22) Filed: Jan. 16, 2008

(30) Foreign Application Priority Data
Jan. 17, 2007 (JP) 2007-007567

(51) Int. Cl. F04B 17/03; H01L 41/09

(52) U.S. Cl. 417/413.2; 310/357

(57) ABSTRACT

A piezoelectric pump includes a piezoelectric vibrator whose periphery is fluid-tightly sealed, and a pump chamber and an air chamber that are formed on front and rear sides of the piezoelectric vibrator. The piezoelectric pump vibrates the piezoelectric vibrator to perform a pumping operation. The piezoelectric vibrator includes: a shim that is formed of a conductive thin metal plate and has one surface abutting on the pump chamber; and a laminate of a plurality of piezoelectric element layers that is formed on the other surface of the shim so as to face the air chamber or the pumping chamber. The plurality of piezoelectric element layers are polarized and connected to wiring lines such that the amplitude of the vibration of the piezoelectric vibrator is larger than that of a piezoelectric vibrator including a single-layer piezoelectric element.

### CLAIM OF PRIORITY

This application claims benefit of the Japanese Patent Application No. 2007-007567 filed on Jan. 17, 2007, the entire content of which is hereby incorporated by reference.

### BACKGROUND

1. Field of the Invention

The present invention relates to a piezoelectric pump that uses the vibration of a piezoelectric vibrator to perform a pumping operation.

2. Description of the Related Art

In general, a piezoelectric pump includes a piezoelectric vibrator whose periphery is fluid-tightly sealed, a pump chamber and an air chamber provided on the front and rear sides of the piezoelectric vibrator, and a pair of check valves (including a check value that allows the flow of liquid to the pump chamber and a check valve that allows the flow of liquid from the pump chamber) that are provided on a pair of flow passages communicating with the pump chamber and allow liquid to flow in opposite directions. When the piezoelectric vibrator is vibrated, the volume of the pump chamber varies, which causes one of the pair of check valves to be opened and the other check value to be closed. This operation is repeated to perform a pumping operation. Such a piezoelectric pump has been used as, for example, a coolant circulating pump for a water-cooled notebook computer. This type of piezoelectric vibrator is disclosed in, for example, JP-A-10-225146, Japanese Utility Model Registration No. 2606595, and JP-A-2003-209302.

The piezoelectric vibrators are classified into a unimorph type in which a piezoelectric element is laminated on one surface of a shim and a bimorph type in which piezoelectric elements are laminated on both surfaces of a shim. The bimorph type has an advantage in that it can increase the amplitude of the vibration of the piezoelectric vibrator to be larger than that in the unimorph type, but has a problem in that the water resistance and the electric insulation thereof are lowered with time since the piezoelectric element contacts liquid in the pump chamber. Meanwhile, the unimorph type does not have problems in the water resistance and the electric insulation since the shim serves as a liquid contact sheet. However, in the unimorph type, the amplitude of the vibration of the piezoelectric vibrator is smaller than that in the bimorph type, and it is difficult to discharge a sufficient amount of liquid (to improve the efficiency of a pump).

### SUMMARY

An object of the invention is to provide a piezoelectric pump capable of increasing the amplitude of the vibration of a piezoelectric vibrator while ensuring the water resistance and electric insulation of the piezoelectric vibrator, thereby improving the efficiency of a pumping operation.

According to an embodiment of the invention, in order to ensure the water resistance and the electric insulation of a piezoelectric vibrator, the unimorph type in which one surface of a shim serves as a liquid contact surface and a piezoelectric element is provided on the other surface of the shim is adopted, and in order to increase the amplitude of the vibration of the piezoelectric vibrator, a plurality of piezoelectric element layers are polarized and connected to wiring lines such that the amplitude of the vibration of the piezoelectric vibrator is larger than that in the structure in which a piezoelectric element has a single piezoelectric element layer.

The polarization direction and wiring structure of the piezoelectric element may be a series type or a parallel type.

In the parallel type, practically, a plurality of layer piezoelectric elements form a lower piezoelectric element layer and an upper piezoelectric element layer that are electrically insulated from each other. Each of the lower piezoelectric element layer and the upper piezoelectric element layer may be formed in a single-layer structure including only one piezoelectric element layer or a multi-layer structure including a plurality of piezoelectric element layers. In the single-layer structure, the lower piezoelectric element layer and the upper piezoelectric element layer are polarized in the same direction, and the lower piezoelectric element layer and the upper piezoelectric element layer are electrically connected in parallel to each other. In the multi-layer structure, adjacent piezoelectric element layers are electrically connected in parallel to each other and polarized in opposite directions. When laminates of the lower piezoelectric element layer and the upper piezoelectric element layer are used, it is possible to lower a driving voltage, as compared to the structure in which a single lower piezoelectric element layer and a single upper piezoelectric element layer are formed.

Meanwhile, in the series type, among a plurality of piezoelectric element layers, adjacent piezoelectric element layers are polarized in opposite directions, and the piezoelectric element layers are electrically connected in series to one another. In the series type, the plurality of piezoelectric element layers form a lower piezoelectric element layer and an upper piezoelectric element layer that are electrically insulated from each other. In addition, practically, the lower piezoelectric element layer and the upper piezoelectric element layer are polarized in opposite directions, and the lower piezoelectric element layer and the upper piezoelectric element layer are electrically connected in series to each other. Alternatively, three or more piezoelectric element layers may be formed.

Further, a plurality of piezoelectric element layers may be subjected to baking and polarizing processes with internal electrodes interposed therebetween.

According to another embodiment, a plurality of piezoelectric element layers may be individually subjected to a baking process, an electrode forming process, and a polarizing process, and then adhered to one another. This structure is particularly effective for a serial type piezoelectric element having a plurality of piezoelectric element layers electrically connected in series to one another.

### BRIEF DESCRIPTION OF THE DRAWINGS

FIG. 1 is a cross-sectional view schematically illustrating a piezoelectric vibrator of a piezoelectric pump according to a first embodiment of the invention;

FIG. 2 is a cross-sectional view illustrating a piezoelectric vibrator according to a second embodiment;

FIG. 3 is a cross-sectional view illustrating a piezoelectric vibrator according to a third embodiment;

FIG. 4 is a cross-sectional view illustrating a piezoelectric vibrator according to a fourth embodiment;

FIG. 5 is a cross-sectional view illustrating a piezoelectric vibrator according to a fifth embodiment;

FIG. 6 is a cross-sectional view illustrating a piezoelectric vibrator according to a sixth embodiment;

FIG. 7 is a cross-sectional view illustrating a piezoelectric vibrator according to a seventh embodiment;

FIG. 8 is a cross-sectional view illustrating a piezoelectric vibrator according to an eighth embodiment;

FIG. 9 is a cross-sectional view illustrating a connection structure of a piezoelectric vibrator according to a ninth embodiment;

FIG. 10 is a cross-sectional view illustrating the piezoelectric vibrator according to the ninth embodiment;

FIG. 11 is plan view illustrating an example of the piezoelectric pump according to the invention;

FIG. 12 is a cross-sectional view taken long the line XII-XII of FIG. 11; and

FIG. 13 is an exploded perspective view illustrating the piezoelectric pump.

### DESCRIPTION OF THE EMBODIMENTS

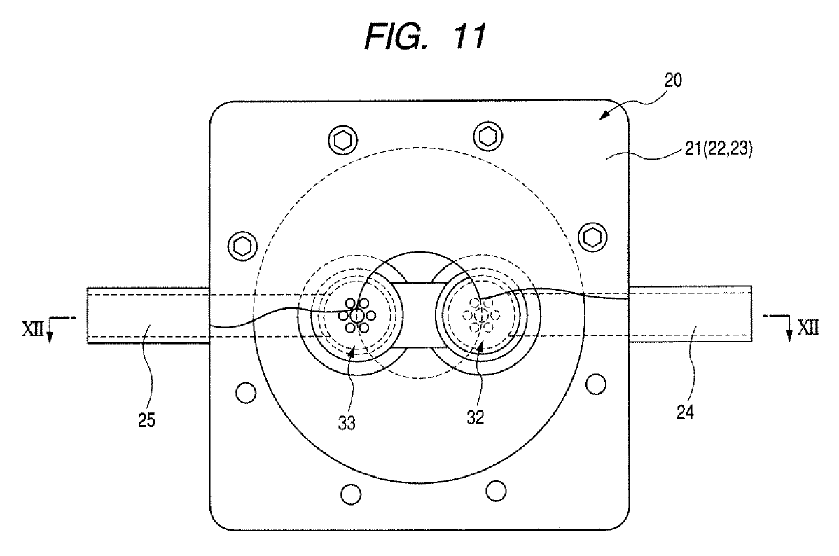

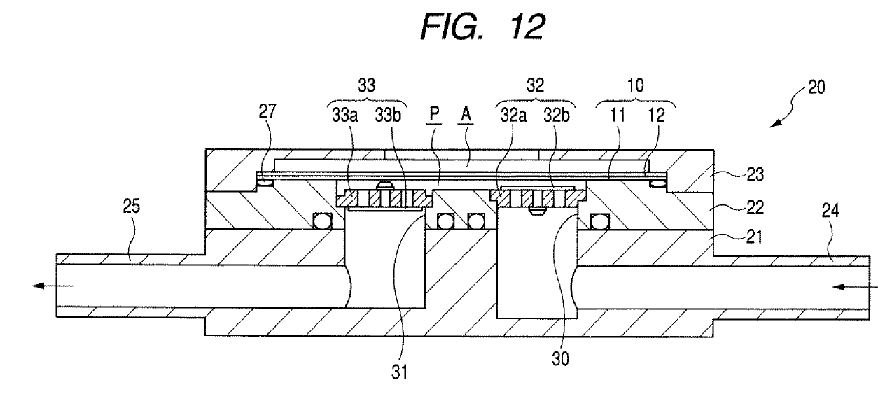

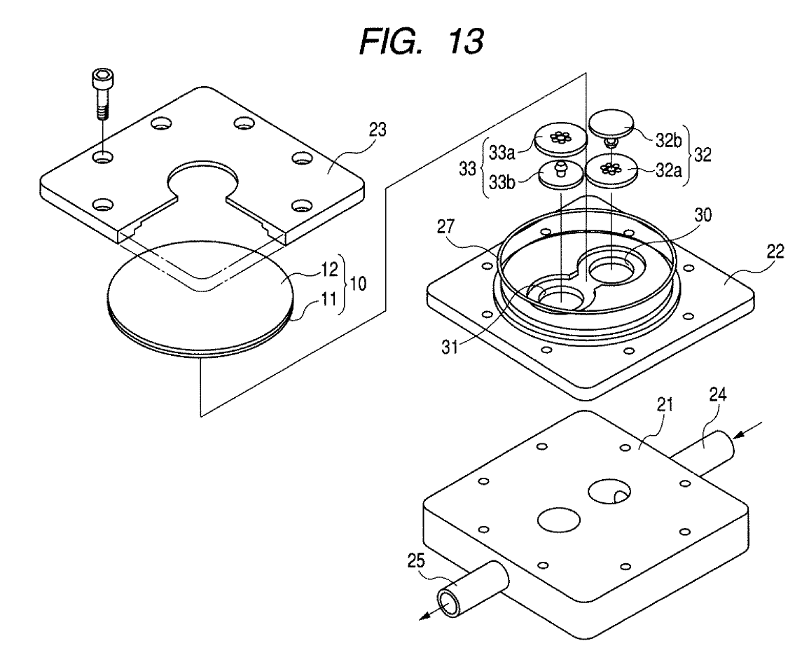

FIGS. 11 to 13 are diaphragms illustrating a piezoelectric pump 20 according to an embodiment of the invention. The piezoelectric pump 20 has a lower housing 21, a middle housing 22, and an upper housing 23 laminated on the bottom in this order.

The lower housing 21 is provided with an inlet port 24 and a discharge port 25 for a coolant (liquid). A piezoelectric vibrator 10 is fluid-tightly provided between the middle housing 22 and the upper housing 23 with an O ring 27 interposed therebetween, and a pump chamber P is formed between the piezoelectric vibrator 10 and the middle housing 22. An air chamber A is formed between the piezoelectric vibrator 10 and the upper housing 23. The air chamber A may be opened or airtightly sealed.

An intake passage 30 through which the inlet port 24 and the pump chamber P communicate with each other, and a discharge passage 31 through which the pump chamber P and the discharge port 25 communicate with each other are formed in the lower housing 21 and the middle housing 22. Check valves (umbrellas) 32 and 33 are provided in the intake passage 30 and the discharge passage 31 of the middle housing 22, respectively. The check valve 32 is a suction check value that allows the flow of liquid from the inlet port 24 to the pump chamber P, but prevents the flow of liquid in the opposite direction thereof. The check valve 33 is a discharge check value that allows the flow of liquid from the pump chamber P to the discharge port 25, but prevents the flow of liquid in the opposite direction thereof.

The check valves 32 and 33 according to the embodiment shown in FIGS. 11 to 13 have the same structure, and include substrates 32a and 33a having openings formed therein that are adhered to or fixed to the passages by fusing, and umbrellas 32b and 33b that are formed of an elastic material and mounted to the substrates 32a and 33a, respectively.

In the piezoelectric pump, when the piezoelectric vibrator 10 is elastically deformed (vibrated) in the positive and negative directions, the suction check valve 32 is opened, and the discharge check value 33 is closed during a process of increasing the volume of the pump chamber P. As a result, a liquid flows from the inlet port 24 to the pump chamber P. Meanwhile, during a process of decreasing the volume of the pump chamber P, the discharge check valve 33 is opened, and the suction check valve 32 is closed. As a result, a liquid flows from the pump chamber P to the discharge port 25. Therefore, it is possible to perform a pumping operation by elastically deforming (vibrating) the piezoelectric vibrator 10 continuously in the positive and negative directions.

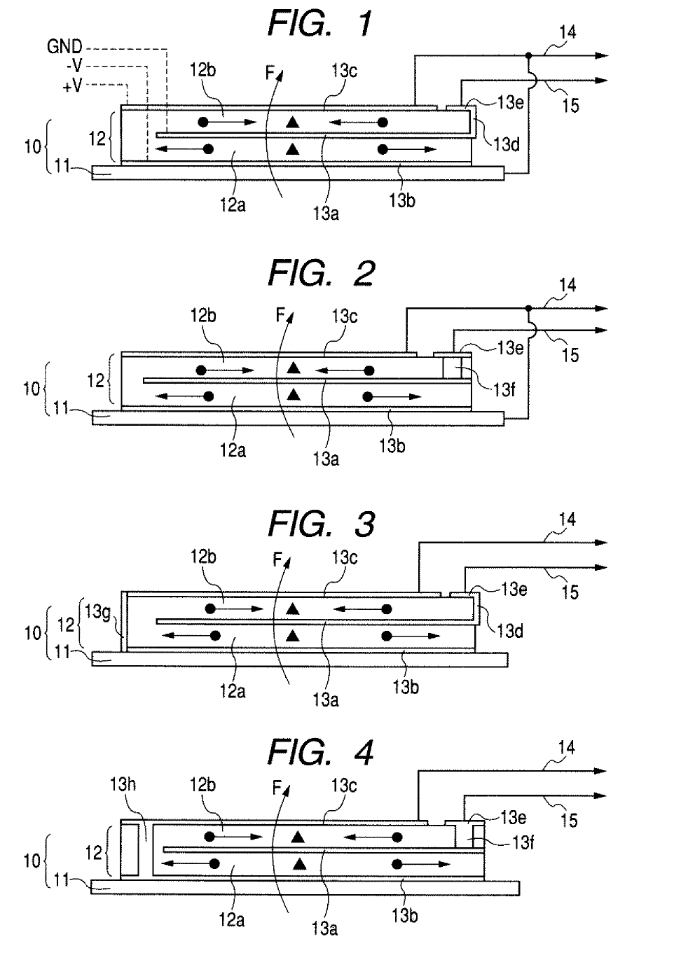

This embodiment is characterized in the structure of the piezoelectric vibrator 10 of the piezoelectric pump 20 having the above-mentioned structure. Next, the structure of piezoelectric vibrators 10 according to exemplary embodiments will be described in detail with reference to FIGS. 1 to 10.

The piezoelectric vibrator 10 includes a shim 11 abutting on the pump chamber P and a laminated piezoelectric element 12 abutting on the air chamber A.

FIG. 1 is a diaphragm illustrating a piezoelectric vibrator 10 according to a first embodiment. The laminated piezoelectric element 12 has a two-layer structure of a lower piezoelectric element layer 12a and an upper piezoelectric element layer 12b laminated on the shim 11 in this order, and an intermediate electrode layer 13a is interposed between the lower piezoelectric element layer 12a and the upper piezoelectric element layer 12b. The intermediate electrode layer 13a serves as a neutral layer that electrically insulates the lower piezoelectric element layer 12a from the upper piezoelectric element layer 12b. The lower piezoelectric element layer 12a and the upper piezoelectric element layer 12b are polarized in the same direction, as represented by arrows (triangles) in the drawings. As known in the art, when positive and negative voltages are applies to the piezoelectric element (layer), the piezoelectric element is deformed in the direction in which the surface area thereof increases or decreases. The lower piezoelectric element layer 12a close to the shim 11 is electrically connected to the shim 11 through a shim-side electrode layer 13b. The shim 11 and a surface electrode layer 13c that is provided on one surface of the upper piezoelectric element layer 12b facing the air chamber A are electrically connected to a first feeder line 14. An intermediate electrode layer 13a is electrically connected to a second feeder line 15 through a side electrode 13d formed on the side of the upper piezoelectric element layer 12b and a lead electrode 13e formed on the surface of the upper piezoelectric element layer 12b. That is, the lower piezoelectric element layer 12a and the upper piezoelectric element layer 12b are electrically connected in parallel to each other. The shim 11 is formed of a thin plate that is made of a metallic material, such as stainless steel or 42 alloy, and has a thickness of about 50 to about 300 μm. The overall thickness of the laminated piezoelectric element 12 is in a range of about 50 to about 600 μm.

When an alternating electric field is applied between the first feeder line 14 and the second feeder line 15, at the moment when a positive voltage is applied to the first feeder line 14 and a negative voltage is applied to the second feeder line 15, as represented by arrows in FIG. 1, the surface area of the lower piezoelectric element layer 12a increases, and the surface area of the upper piezoelectric element layer 12b decreases. Then, the laminated piezoelectric element 12 deforms the piezoelectric vibrator 10 to protrude downward in FIG. 1 (generates a couple of forces F). In this state, when the levels of the voltages applied to the first feeder line 14 and the second feeder line 15 are reversed, the laminated piezoelectric element 12 deforms the piezoelectric vibrator 10 to protrude upward in FIG. 1. When this operation is repeated, the piezoelectric vibrator 10 is vibrated. In this case, the amplitude of the vibration is larger than that in the structure in which the laminated piezoelectric element 12 includes a single piezoelectric element layer.

FIG. 2 is a diaphragm illustrating a piezoelectric vibrator 10 according to a second embodiment. In the piezoelectric vibrator 10 according to the second embodiment, an intermediate electrode layer 13a and a lead electrode 13e are electrically connected to each other by a through hole electrode 13f, instead of the side electrode 13d. In the second embodiment, similar to the first embodiment, the amplitude of the vibration of the piezoelectric vibrator 10 is larger than that in the structure in which the laminated piezoelectric element 12 includes a single piezoelectric element layer.

FIGS. 3 and 4 show third and fourth embodiments in which connecting portions between the laminated piezoelectric element 12 and the first and second feeder lines 14 and 15 are formed on one surface of the laminated piezoelectric element 12 facing the air chamber A.

FIG. 3 is a diaphragm illustrating a piezoelectric vibrator 10 according to the third embodiment. In the piezoelectric vibrator 10 according to the third embodiment, which is a modification of the first embodiment shown in FIG. 1, a shim-side electrode layer 13b (11) and a surface electrode layer 13c are electrically connected to each other by a side connection electrode 13g formed on the side of the laminated piezoelectric element 12. According to the third embodiment, the amplitude of the vibration of the piezoelectric vibrator 10 is larger than that in the structure in which the laminated piezoelectric element 12 includes a single piezoelectric element layer, and it is possible to easily connect wiring lines to the laminated piezoelectric element 12.

FIG. 4 shows a piezoelectric vibrator 10 according to the fourth embodiment. In the piezoelectric vibrator 10 according to the fourth embodiment, which is a modification of the second embodiment shown in FIG. 2, a shim-side electrode layer 13b (shim 11) and a surface electrode layer 13c are electrically connected to each other by a through hole electrode 13h that is formed so as to be laid across a lower piezoelectric element layer 12a and an upper piezoelectric element layer 12b. In the fourth embodiment, similar to the third embodiment, the amplitude of the vibration of the piezoelectric vibrator 10 is larger than that in the structure in which the laminated piezoelectric element 12 includes a single piezoelectric element layer, and it is possible to easily connect wiring lines to the laminated piezoelectric element 12.

In the above-described first to fourth embodiments, the laminated piezoelectric element 12 including the lower piezoelectric element layer 12a and the upper piezoelectric element layer 12b electrically connected in parallel to each other can be manufactured as follows. First, piezoelectric powder containing Pb(Zr, Ti) O₃ having an average particle diameter of about 1.0 μm as main components is mixed with a predetermined amount of organic binder, plasticizer, or organic solvent to make slurry. Then, a piezoelectric green sheet having a predetermined thickness (for example, about 60 to about 70 μm) is made from the slurry by a doctor blade method. The piezoelectric green sheet is cut into a circular shape in plan view by die cutting, and a plurality of sheets overlap each other to form the lower piezoelectric element layer 12a and the upper piezoelectric element layer 12b. Then, electrode layers (the intermediate electrode layer 13a, through hole electrode 13f, and so on) are formed between the lower piezoelectric element layer 12a and the upper piezoelectric element layer 12b and on the surfaces thereof. The laminated structure is baked at a high temperature to manufacture the laminated piezoelectric element 12, and then a polarizing process is performed on the lower piezoelectric element layer 12a and the upper piezoelectric element layer 12b to be polarized in the same direction. In FIG. 1, broken lines indicate connection between wiring lines and the layers to perform the polarizing process. That is, the shim-side electrode layer 13b is connected to a negative (−V) voltage line, the surface electrode layer 13c is connected to a positive (+V) voltage line, and the intermediate electrode layer 13a is connected to a ground (GND) line. Then, voltages are applied to the electrodes under predetermined conditions to polarize the lower piezoelectric element layer 12a and the upper piezoelectric element layer 12b in the same direction. In FIGS. 2 to 4, connection between the layers and wiring lines for the polarizing process is not shown, but, in the second to fourth embodiments, the same connection method as that shown in FIG. 1 is used.

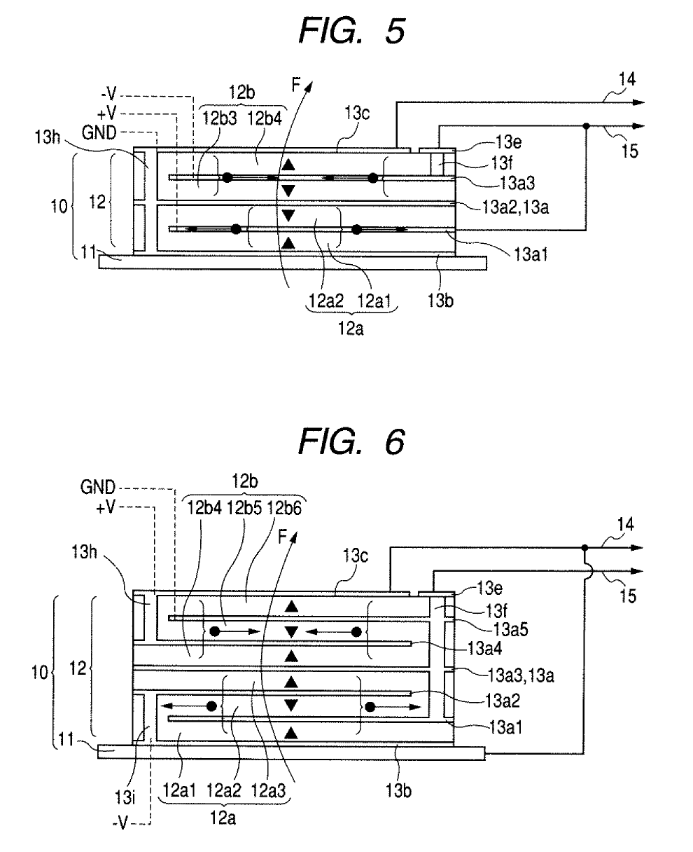

FIGS. 5 and 6 shows fifth and sixth embodiments, which are modifications of the fourth embodiment shown in FIG. 4, in which a plurality of laminated piezoelectric elements 12 are laminated (a lower piezoelectric element layer 12a and an upper piezoelectric element layer 12b each have a multi-layer structure).

FIG. 5 is a diaphragm illustrating a piezoelectric vibrator 10 according to the fifth embodiment. In the piezoelectric vibrator 10 according to the fifth embodiment, the laminated piezoelectric element 12 is formed in a four-layer structure of a first piezoelectric element layer 12a1, a second piezoelectric element layer 12a2, a third piezoelectric element layer 12b3, and a fourth piezoelectric element layer 12b4 laminated from a shim 11 in this order. In addition, first to third internal electrode layers 13a1, 13a2, and 13a3 are formed among the piezoelectric element layers 12a1, 12a2, 12b3, and 12b4. The polarization directions of the first to fourth piezoelectric element layers 12a1, 12a2, 12b3, and 12b4 are represented by arrows (triangles) in the drawings. The adjacent first and second piezoelectric element layers 12a1 and 12a2 are electrically connected in parallel to each other, and the polarization directions thereof are reversed. A pair of the first piezoelectric element layer 12a1 and the second piezoelectric element layer 12a2 forms the lower piezoelectric element layer 12a that is disposed below one surface of the second internal electrode layer 13a2 facing the shim 11. The adjacent third and fourth piezoelectric element layers 12b3 and 12b4 are electrically connected in parallel to each other, and the polarization directions thereof are reversed. A pair of the third piezoelectric element layer 12b3 and the fourth piezoelectric element layer 12b4 forms the upper piezoelectric element layer 12b that is disposed on the other surface of the second internal electrode layer 13a2 facing the air chamber A. In the fifth embodiment, the intermediate electrode layer 13a serves as a neutral layer that electrically insulates the lower piezoelectric element layer 12a (the second piezoelectric element layer 12a2) from the upper piezoelectric element layer 12b (the third piezoelectric element layer 12b3).

When positive and negative voltages are applied, the laminated piezoelectric element 12 is deformed in the direction in which the surface area thereof decreases or increases. The shim-side electrode layer 13b provided on one surface of the first piezoelectric element layer 12a1 facing the shim 11, the second internal electrode layer 13a2 (the intermediate electrode layer 13a>, and the surface electrode layer 13c formed on one surface of the fourth piezoelectric element layer 12b4 facing the air chamber A are electrically connected to one another by a through hole electrode 13h. In addition, the surface electrode layer 13c is electrically connected to a first feeder line 14. The third internal electrode layer 13a3 interposed between the third piezoelectric element layer 12b3 and the fourth piezoelectric element layer 12b4 is electrically connected to a lead electrode 13e formed on the surface of the fourth piezoelectric element layer 12b4 by a through hole electrode 13f. The lead electrode 13e and the first internal electrode layer 13a1 interposed between the first piezoelectric element layer 12a1 and the second piezoelectric element layer 12a2 are electrically connected to a second feeder line 15. That is, the lower piezoelectric element layer 12a (the first piezoelectric element layer 12a1 and the second piezoelectric element layer 12a2) is electrically connected in parallel to the upper piezoelectric element layer 12b (the third piezoelectric element layer 12b3 and the fourth piezoelectric element layer 12b4).

When an alternating electric field is applied between the first feeder line 14 and the second feeder line 15, at the moment when a positive voltage is applied to the first feeder line 14 and a negative voltage is applied to the second feeder line 15, as represented by arrows in FIG. 5, the surface area of the lower piezoelectric element layer 12a increases, and the surface areas of the upper piezoelectric element layer 12b decreases. Then, the laminated piezoelectric element 12 deforms the piezoelectric vibrator 10 to protrude downward in FIG. 5 (generates a couple of forces F). In this state, when the levels of the voltages applied to the first feeder line 14 and the second feeder line 15 are reversed, the laminated piezoelectric element 12 deforms the piezoelectric vibrator 10 to protrude upward in FIG. 5. When this operation is repeated, the piezoelectric vibrator 10 is vibrated. In this case, the amplitude of the vibration of the piezoelectric vibrator 10 is larger than that in the structure in which a piezoelectric element of the piezoelectric vibrator 10 includes a single piezoelectric element layer and that in the structure in which the lower piezoelectric element layer 12a and the upper piezoelectric element layer 12b each include a single piezoelectric element layer.

The polarization characteristics of the first to fourth piezoelectric element layers 12a1, 12a2, 12b3, and 12b4 are obtained by connecting the first internal electrode layer 13a1 to a positive (+V) voltage line, the shim-side electrode layer 13b, the intermediate electrode layer 13a (the second internal electrode layer 13a2), and the surface electrode layer 13c to a ground (GND) line, and the third internal electrode layer 13a3 to a negative (−V) voltage line, as represented by broken lines in FIG. 5, and by applying voltages to the layers under predetermined conditions.

Similar to the first embodiment, the overall thickness of the laminated piezoelectric element 12 is in a range of about 50 to about 600 μm. According to the fifth embodiment, in order to obtain the same displacement, the piezoelectric vibrator 10 is supplied with a driving voltage that is a quarter of the driving voltage applied to the piezoelectric vibrator 10 including a piezoelectric element having a single piezoelectric element layer which has the same thickness as that of the four-layer laminated piezoelectric element 12. As a result, it is possible to reduce the driving voltage.

FIG. 6 is a diaphragm illustrating a piezoelectric vibrator 10 according to a sixth embodiment. In the piezoelectric vibrator 10 according to the sixth embodiment, a laminated piezoelectric element 12 is formed in a six-layer structure of a first piezoelectric element layer 12a1, a second piezoelectric element layer 12a2, a third piezoelectric element layer 12a3, a fourth piezoelectric element layer 12b4, a fifth piezoelectric element layer 12b5, and a sixth piezoelectric element layer 12b6 formed on a shim 11 in this order. In addition, first to fifth internal electrode layers 13a1, 13a2, 13a3, 13a4, and 13a5 are provided among the piezoelectric element layers 12a1 to 12a3 and 12b4 to 12b6. The polarization directions of the first to sixth piezoelectric element layers 12a1 to 12a3 and 12b4 to 12b6 are represented by arrows (triangles) in FIG. 6. The adjacent first and second piezoelectric element layers 12a1 and 12a2 are electrically connected in parallel to each other, and the polarization directions thereof are reversed. The adjacent second and third piezoelectric element layers 12a2 and 12a3 are electrically connected in parallel to each other, and the polarization directions thereof are reversed. A three-layer structure of the first piezoelectric element layer 12a1, the second piezoelectric element layer 12a2, and the third piezoelectric element layer 12a3 forms the lower piezoelectric element layer 12a that is disposed below one surface of the third internal electrode layer 13a3 facing the shim 11. The adjacent fourth and fifth piezoelectric element layers 12b4 and 12b5 are electrically connected in parallel to each other, and the polarization directions thereof are reversed. The adjacent fifth and sixth piezoelectric element layers 12b5 and 12b6 are electrically connected in parallel to each other, and the polarization directions thereof are reversed A three-layer structure of the fourth piezoelectric element layer 12b4, the fifth piezoelectric element layer 12b5, and the sixth piezoelectric element layer 12b6 forms the upper piezoelectric element layer 12b that is disposed on the other surface of the third internal electrode layer 13a3 facing the air chamber A. In the sixth embodiment, the intermediate electrode layer 13a serves as a neutral layer that electrically insulates the lower piezoelectric element layer 12a (the third piezoelectric element layer 12a3) from the upper piezoelectric element layer 12b (the fourth piezoelectric element layer 12b4).

When positive and negative voltages are applied, the laminated piezoelectric element 12 is deformed in the direction in which the surface area thereof decreases or increases. The first internal electrode layer 13a1 interposed between the first piezoelectric element layer 12a1 and the second piezoelectric element layer 12a2, the intermediate electrode layer 13a (the third internal electrode layer 13a3), the fifth internal electrode layer 13a5 interposed between the fifth piezoelectric element layer 12b5 and the sixth piezoelectric element layer 12b6, and a lead electrode 13e formed on one surface of the sixth piezoelectric element layer 12b6 facing the air chamber A are electrically connected to one another by a through hole electrode 13f. In addition, the lead electrode 13e is electrically connected to a second feeder line 15. The shim-side electrode layer 13b formed on one surface of the first piezoelectric element layer 12a1 facing the shim 11 and the second internal electrode layer 13a2 interposed between the second piezoelectric element layer 12a2 and the third piezoelectric element layer 12a3 are electrically connected to each other by a through hole electrode 13i. In addition, the shim-side electrode layer 13b (shim 11) is electrically connected to a first feeder line 14. The fourth internal electrode layer 13a4 interposed between the fourth piezoelectric element layer 12b4 and the fifth piezoelectric element layer 12b5 is electrically connected to the surface electrode layer 13c that is formed on one surface of the sixth piezoelectric element layer 12b6 facing the air chamber A by a through hole electrode 13h. In addition, the surface electrode layer 13c is electrically connected to the first feeder line 14. That is, the lower piezoelectric element layer 12a is electrically connected in parallel to the upper piezoelectric element layer 12b.

When an alternating electric field is applied between the first feeder line 14 and the second feeder line 15, at the moment when a positive voltage is applied to the first feeder line 14 and a negative voltage is applied to the second feeder line 15, as represented by arrows in FIG. 6, the surface area of the lower piezoelectric element layer 12a increases, and the surface areas of the upper piezoelectric element layer 12b decreases. Then, the laminated piezoelectric element 12 deforms the piezoelectric vibrator 10 to protrude downward in FIG. 6 (generates a couple of forces F). In this state, when the levels of the voltages applied to the first feeder line 14 and the second feeder line 15 are reversed, the laminated piezoelectric element 12 deforms the piezoelectric vibrator 10 to protrude upward in FIG. 6. When this operation is repeated, the piezoelectric vibrator 10 is vibrated. In this case, the amplitude of the vibration is larger than that in the structure in which a piezoelectric element of the piezoelectric vibrator 10 includes a single piezoelectric element layer, and that in the structure in which the lower piezoelectric element layer 12a and the upper piezoelectric element layer 12b each include a single piezoelectric element layer.

The polarization characteristics of the first to sixth piezoelectric element layers 12a1 to 12a3 and 12b3 to 12b6 are obtained by connecting the surface electrode layer 13c to a positive (+V) voltage line, the shim-side electrode layer 13b to a negative (−V) voltage line, and the intermediate electrode layer 13a (the third internal electrode layer 13a3) to a ground (GND) line, as represented by broken lines in FIG. 6, and by applying voltages to the layers under predetermined conditions.

Similar to the first embodiment, the overall thickness of the laminated piezoelectric element 12 is in a range of about 50 to about 600 μm. According to the sixth embodiment, in order to obtain the same displacement, the piezoelectric vibrator 10 is supplied with a driving voltage that is one-sixth of the driving voltage applied to the piezoelectric vibrator 10 including a piezoelectric element having a single piezoelectric element layer which has the same thickness as that of the sixth-layer laminated piezoelectric element 12. As a result, it is possible to reduce the driving voltage. As the number of laminates of the upper piezoelectric element layer 12a and the lower piezoelectric element layer 12b increases, a lower driving voltage is required to obtain the same displacement.

Although the first to sixth embodiments using the parallel type laminated piezoelectric element 12 have been described above, the invention can be applied to a series type laminated piezoelectric element. The series type laminated piezoelectric element is not affected by the inversion of polarization, which makes it possible to lengthen the life span of a piezoelectric vibrator and to increase a voltage to improve the function thereof without limiting the intensity of a driving voltage.

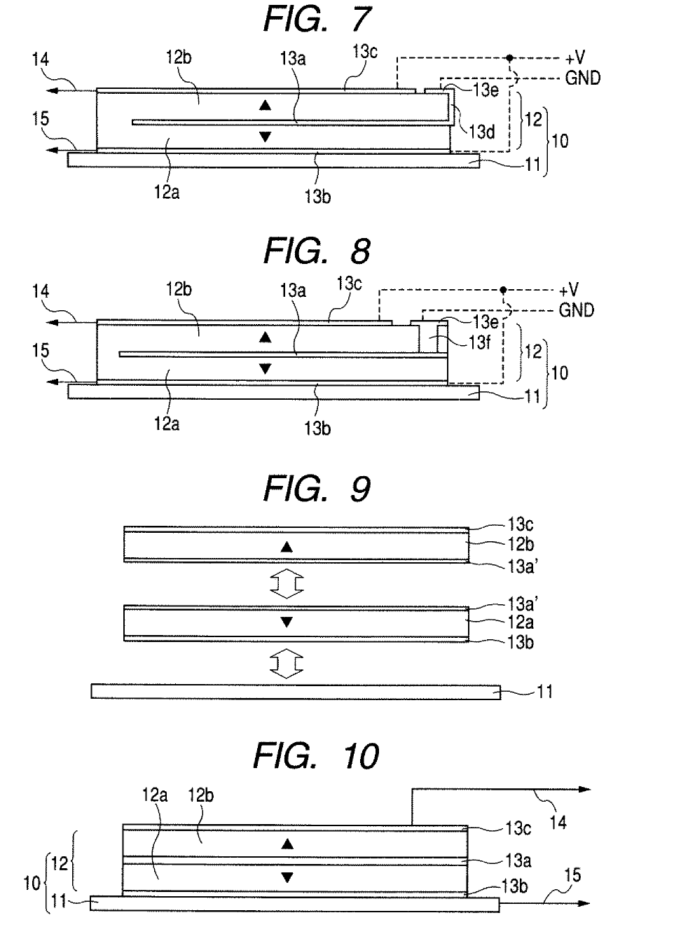

FIGS. 7 to 10 are diaphragms illustrating embodiments in which a lower piezoelectric element layer 12a is laminated on an upper piezoelectric element layer 12b such that their polarization directions are opposite to each other, and the lower piezoelectric element layer 12a and the upper piezoelectric element layer 12b are electrically connected in series to each other.

FIG. 7 is a diaphragm illustrating a piezoelectric vibrator 10 according to a seventh embodiment. The piezoelectric vibrator 10 of the seventh embodiment has the same electrode structure (an intermediate electrode layer 13a, a shim-side electrode layer 13b, a surface electrode layer 13c, a side electrode 13d, and a lead electrode 13e) as that of the first embodiment (FIG. 1), but differs from that of the first embodiment in the polarization directions of the lower piezoelectric element layer 12a and the upper piezoelectric element layer 12b. The lower piezoelectric element layer 12a and the upper piezoelectric element layer 12b are electrically connected in series to each other, and are supplied with a driving voltage through a first feeder line 14 electrically connected to the surface electrode layer 13c and a second feeder line 15 electrically connected to the shim-side electrode layer 13b. The intermediate electrode layer 13a serves as a neutral layer that electrically insulates the lower piezoelectric element layer 12a from the upper piezoelectric element layer 12b. The overall thickness of the laminated piezoelectric element 12 is in a range of about 50 to about 600 μm.

In the seventh embodiment, the polarization directions of the lower piezoelectric element layer 12a and the upper piezoelectric element layer 12b are reversed. Therefore, when an alternating electric field is applied between the first feeder line 14 and the second feeder line 15, the surface area of one of the lower piezoelectric element layer 12a and the upper piezoelectric element layer 12b increases, but the surface area of the other piezoelectric element layer decreases. Thus, similar to the structure as shown in FIG. 1, the amplitude of the vibration of the piezoelectric vibrator 10 is larger than that in the structure in which a piezoelectric element of the piezoelectric vibrator 10 includes only a single piezoelectric element layer.

The side electrode 13d and the lead electrode 13e are needed to connect the layers and wiring lines, in order to polarize the lower piezoelectric element layer 12a and the upper piezoelectric element layer 12b in opposite directions. That is, it is possible to polarize the lower piezoelectric element layer 12a and the upper piezoelectric element layer 12b in opposite directions by connecting both the shim-side electrode layer 13b and the surface electrode layer 13c to a positive voltage line (+V) and connecting the intermediate electrode layer 13a to the ground (GND) through the side electrode 13d and the lead electrode 13e, as represented by broken lines in FIG. 7.

FIG. 8 is a diaphragm illustrating a piezoelectric vibrator 10 according to an eighth embodiment. In the piezoelectric vibrator 10 according to the eighth embodiment, an intermediate electrode layer 13a and a lead electrode 13e are electrically connected to each other by a through hole electrode 13f, instead of the side electrode 13d according to the seventh embodiment. That is, the eighth embodiment has the same electrode structure as the second embodiment (FIG. 2), and is similar to the seventh embodiment (FIG. 7) in the polarization directions of a lower piezoelectric element layer 12a and an upper piezoelectric element layer 12b and a connection structure therebetween.

FIGS. 9 and 10 are diaphragms illustrating a piezoelectric vibrator 10 according to a ninth embodiment. According to the ninth embodiment, it is possible to easily manufacture a lower piezoelectric element layer 12a and an upper piezoelectric element layer 12b connected in series to each other. In the laminated piezoelectric elements 12 according to the first to eighth embodiments, the lower piezoelectric element layer 12a, the upper piezoelectric element layer 12b, and the electrode layers 13a to 13f are integrally formed, and then wiring lines are connected to the layers in order to polarize the piezoelectric element layers, as represented by broken lines in FIGS. 1, 2, and 5 to 8. Therefore, the electrode structure becomes complicated. In contrast, in the ninth embodiment, as shown in FIG. 9, the lower piezoelectric element layer 12a and the upper piezoelectric element layer 12b are individually formed, a polarization process is performed on the lower piezoelectric element layer 12a and the upper piezoelectric element layer 12b to polarize them in opposite directions, and the lower piezoelectric element layer 12a and the upper piezoelectric element layer 12b are electrically connected in series to each other. Specifically, the lower piezoelectric element layer 12a is formed as follows: a piezoelectric green sheet is cut into a circular shape in plan view by dies cutting; a single-layer sheet or a laminate of a plurality of sheets is baked at a high temperature; electrode layers (a shim-side electrode layer 13b and an intermediate electrode layer 13a′) are formed on the front and rear surfaces of the baked circular sheet; and a polarizing process is performed on the circular sheet using the electrode layers formed on the front and rear surfaces thereof. The upper piezoelectric element layer 12b is formed as follows: a piezoelectric green sheet is cut into a circular shape in plan view by dies cutting; a single-layer sheet or a laminate of a plurality of sheets is baked at a high temperature; electrode layers (a surface electrode layer 13c and an intermediate electrode layer 13a′) are formed on the front and rear surfaces of the baked circular sheet; and a polarizing process is performed on the circular sheet using the electrode layers formed on the front and rear surfaces thereof to polarize the circular sheet in a direction opposite to the polarization direction of the lower piezoelectric element layer 12a. Then, as shown in FIG. 9, the shim-side electrode layer 13b of the lower piezoelectric element layer 12a is adhered to a shim 11, and the intermediate electrode layers 13a′ of the lower piezoelectric element layer 12a and the upper piezoelectric element layer 12b are adhered to each other. In this case, for example, a conductive resin adhesive may be used to bond the layers. In this way, as shown in FIG. 10, the laminated piezoelectric element 12 including the lower piezoelectric element layer 12a and the upper piezoelectric element layer 12b that are polarized in opposite directions and electrically connected in series to each other is obtained, and thus the piezoelectric vibrator 10 provided with the laminated piezoelectric element 12 is manufactured. The overall thickness of the laminated piezoelectric element 12 is in a range of about 50 to about 600 μm. According to the ninth embodiment, the side electrode 13d shown in FIG. 7 and the through hole electrode 13f shown in FIG. 8 are not needed. Therefore, it is possible to easily form the series type laminated piezoelectric element 12. In addition, the ninth embodiment has the same connection structure as the seventh embodiment (FIG. 7).

According to the above-described embodiments, one surface of the shim 11 abuts on the pump chamber P, and the laminated piezoelectric element 12 including a plurality of piezoelectric element layers is formed on the other surface of the shim 11 so as to face the air chamber A. In the laminated piezoelectric element 12, the piezoelectric element layers are polarized and connected to wiring lines such that the amplitude of the vibration of the piezoelectric vibrator 10 is larger than that in the structure in which the laminated piezoelectric element 12 is a single-layer piezoelectric element. As a result, it is possible to increase the amplitude of the vibration of a piezoelectric vibrator while ensuring water resistance and electrical insulation, thereby improving the efficiency of a pump.

Alternatively, one surface of the shim 11 may abut on the pump chamber P, the laminated piezoelectric element 12 including a plurality of piezoelectric element layers may be formed on the one surface abutting on the pump chamber P, and a resin cover film (not shown) having water resistance may be closely adhered to the laminated piezoelectric element 12. In this case, the cover film is needed, but it is possible to increase the amplitude of the vibration of a piezoelectric vibrator while ensuring water resistance and electrical insulation, thereby improving the efficiency of a pump. In general, in the piezoelectric pump, since the internal pressure of the pump chamber P is higher than that of the air chamber A, the displacement of the air chamber A is larger than that of the pump chamber P in the piezoelectric vibrator. Therefore, when the laminated piezoelectric element 12 is disposed so as to face the pump chamber P, the laminated piezoelectric element 12 is protected from stress by the shim 11, and stress applied to the laminated piezoelectric element 12 is lower than that in the structure in which the laminated piezoelectric element 12 is disposed so as to face the air chamber A. Therefore, it is possible to prevent cracks of the laminated piezoelectric element 12 and lengthen the life span thereof.

1. A piezoelectric pump comprising:
a piezoelectric vibrator whose periphery is fluid-tightly sealed; and
a pump chamber and an air chamber that are formed on front and rear sides of the piezoelectric vibrator,
wherein the piezoelectric vibrator comprises:
a shim that is formed of a conductive thin metal plate and has one surface abutting on the pump chamber; and
a laminate of a plurality of piezoelectric element layers that is formed on the other surface of the shim so as to face the air chamber,
wherein the plurality of piezoelectric element layers are polarized and connected to wiring lines such that the amplitude of the vibration of the piezoelectric vibrator is larger than that of a piezoelectric vibrator including a single-layer piezoelectric element, and wherein the piezoelectric vibrator is vibrated to perform a pumping operation.

2. The piezoelectric pump according to claim 1, wherein:
the plurality of piezoelectric element layers form a lower piezoelectric element layer and an upper piezoelectric element layer that are electrically insulated from each other,
the lower piezoelectric element layer and the upper piezoelectric element layer are polarized in the same direction, and
the lower piezoelectric element layer and the upper piezoelectric element layer are electrically connected in parallel to each other.

3. The piezoelectric pump according to claim 1, wherein:
the plurality of piezoelectric element layers form a lower piezoelectric element layer and an upper piezoelectric element layer that are electrically insulated from each other,
each of the lower piezoelectric element layer and the upper piezoelectric element layer is formed in a multi-layer structure of a plurality of piezoelectric element layers,
adjacent piezoelectric element layers in the multi-layer structure are electrically connected in parallel to each other, and
the polarization directions of the adjacent piezoelectric element layers are reversed.

4. The piezoelectric pump according to claim 1, wherein:
among the plurality of piezoelectric element layers, adjacent piezoelectric element layers are polarized in opposite directions, and
the piezoelectric element layers are electrically connected in series to one another.

5. The piezoelectric pump according to claim 4, wherein:
the plurality of piezoelectric element layers form a lower piezoelectric element layer and an upper piezoelectric element layer that are electrically insulated from each other,
the lower piezoelectric element layer and the upper piezoelectric element layer are polarized in opposite directions, and
the lower piezoelectric element layer and the upper piezoelectric element layer are electrically connected in series to each other.

6. The piezoelectric pump according to claim 1, wherein the plurality of piezoelectric element layers are subjected to baking and polarizing processes, with internal electrodes interposed therebetween.

7. The piezoelectric pump according to claim 4, wherein the plurality of piezoelectric element layers are individually subjected to a backing process, an electrode forming process, and a polarizing process, and then adhered to one another.

8. The piezoelectric pump according to claim 5, wherein the plurality of piezoelectric element layers are individually subjected to a backing process, an electrode forming process, and a polarizing process, and then adhered to one another.

9. A piezoelectric pump comprising:
a piezoelectric vibrator whose periphery is fluid-tightly sealed; and
a pump chamber and an air chamber that are formed on front and rear sides of the piezoelectric vibrator,
wherein the piezoelectric vibrator comprises:
a shim that is formed of a conductive thin metal plate and has one surface abutting on the pump chamber; and
a laminate of a plurality of piezoelectric element layers that is formed on the other surface of the shim so as to face the air chamber,
wherein among the plurality of piezoelectric element layers, adjacent piezoelectric element layers are polarized in opposite directions, wherein the plurality of piezoelectric element layers are individually subjected to a backing process, an electrode forming process, and a polarizing process, and then electrically connected in series to one another, and wherein the piezoelectric vibrator is vibrated to perform a pumping operation.

10. A piezoelectric pump comprising:
a piezoelectric vibrator whose periphery is fluid-tightly sealed; and
a pump chamber and an air chamber that are formed on front and rear sides of the piezoelectric vibrator,
wherein the piezoelectric vibrator comprises:
a shim that is formed of a conductive thin metal plate and has one surface abutting on the pump chamber; and
a laminate of a plurality of piezoelectric element layers that is formed on the one surface of the shim,
wherein the plurality of piezoelectric element layers are polarized and connected to wiring lines such that the amplitude of the vibration of the piezoelectric vibrator is larger than that of a piezoelectric vibrator including a single-layer piezoelectric element, and wherein the piezoelectric vibrator is vibrated to perform a pumping operation.
